(19) United States
(12) Patent Application Publication
(10) Pub. No.: US 2023/0275399 A1
(43) Pub. Date: Aug. 31, 2023

(54) SEMICONDUCTOR OPTICAL DEVICE AND METHOD OF MANUFACTURING THE SAME

(71) Applicants: Sumitomo Electric Industries, Ltd., Osaka-shi (JP); National University Corporation Hokkaido University, Sapporo-shi (JP)

(72) Inventors: Naoya KONO, Osaka-shi (JP); Naoki FUJIWARA, Osaka-shi (JP); Kunimasa SAITOH, Sapporo-shi (JP); Takeshi FUJISAWA, Sapporo-shi (JP); Takanori SATO, Sapporo-shi (JP)

(73) Assignees: Sumitomo Electric Industries, Ltd., Osaka-shi (JP); National University Corporation Hokkaido University, Sapporo-shi (JP)

(21) Appl. No.: 18/106,049

(22) Filed: Feb. 6, 2023

(30) Foreign Application Priority Data
Feb. 28, 2022 (JP) 2022-029416
Aug. 12, 2022 (JP) 2022-128619

(51) Int. Cl. H01S 5/10; H01S 5/22; H01S 5/343

(52) U.S. Cl. CPC H01S 5/101; H01S 5/22; H01S 5/3434; H01S 5/1028; H01S 5/34373; H01S 5/1014

(57) ABSTRACT

A semiconductor optical device includes a substrate formed of silicon and having a first optical waveguide and a semiconductor element formed of a III-V compound semiconductor and having a second optical waveguide, the semiconductor element being bonded to an upper surface of the substrate. The first optical waveguide and the second optical waveguide form a directional coupler.

### CROSS REFERENCE TO RELATED APPLICATIONS

This application claims priority based on Japanese Patent Applications No. 2022-029416 filed on Feb. 28, 2022, and No. 2022-128619 filed on Aug. 12, 2022, and the entire contents of the Japanese patent applications are incorporated herein by reference.

### FIELD

The present disclosure relates to a semiconductor optical device and a method of manufacturing the same.

### BACKGROUND

There is known a technique of bonding a semiconductor element formed of a III-V compound semiconductor to a substrate such as an SOI (Silicon On Insulator) substrate (so-called silicon photonics) in which an optical waveguide is formed (for example, Non-PTL 1). [Non-PTL1] R. Kou et al. “Inter-layer light transition in hybrid III-V/Si waveguides integrated by μ-transfer printing” Optics Express 28 (13), 19772-19782, June 2020

### SUMMARY

A semiconductor optical device according to the present disclosure includes a substrate formed of silicon and having a first optical waveguide, and a semiconductor element formed of a III-V compound semiconductor and having a second optical waveguide, the semiconductor element being bonded to an upper surface of the substrate. The first optical waveguide and the second optical waveguide form a directional coupler.

A method of manufacturing a semiconductor optical device according to the present disclosure includes bonding a semiconductor element formed of a III-V compound semiconductor to an upper surface of a substrate formed of silicon and having a first optical waveguide and forming a second optical waveguide at the semiconductor element. The first optical waveguide and the second optical waveguide form a directional coupler.

### BRIEF DESCRIPTION OF DRAWINGS

FIG. 1A is a plan view illustrating a semiconductor optical device according to a first embodiment.

FIG. 1B is an enlarged plan view of a portion of a semiconductor optical device.

FIG. 2A is a cross-sectional view taken along line A-A of FIG. 1B.

FIG. 2B is a cross-sectional view taken along line B-B of FIG. 1B.

FIG. 3A is a diagram illustrating an effective refractive index.

FIG. 3B is a diagram illustrating an effective refractive index.

FIG. 4 is a diagram illustrating a transmittance.

FIG. 5A is a diagram illustrating a dependence of a transmittance on an overlap amount.

FIG. 5B a diagram illustrating a wavelength dependence of a transmittance.

FIG. 6 is a cross-sectional view illustrating a semiconductor optical device according to a modification.

FIG. 7A is a plan view illustrating a semiconductor optical device according to a second embodiment.

FIG. 7B is a cross-sectional view taken along line C-C of FIG. 7A.

FIG. 8A is a plan view illustrating a semiconductor optical device according to a third embodiment.

FIG. 8B is an enlarged plan view of a portion of the semiconductor optical device.

FIG. 9A is a cross-sectional view taken along line D-D of FIG. 8A.

FIG. 9B is a cross-sectional view taken along line E-E of FIG. 8A.

FIG. 10A is a plan view illustrating a method of manufacturing a semiconductor optical device.

FIG. 10B is a cross-sectional view taken along line D-D of FIG. 10A.

FIG. 10C is a cross-sectional view taken along line E-E of FIG. 10A.

FIG. 11A is a plan view illustrating a method of manufacturing a semiconductor optical device.

FIG. 11B is a cross-sectional view taken along line D-D of FIG. 11A.

FIG. 11C is a cross-sectional view taken along line E-E of FIG. 11A.

FIG. 12A is a plan view illustrating a method of manufacturing a semiconductor optical device.

FIG. 12B is a cross-sectional view taken along line D-D of FIG. 12A.

FIG. 13A is a plan view illustrating a semiconductor optical device according to a fourth embodiment.

FIG. 13B is a cross-sectional view taken along line E-E of FIG. 13A.

FIG. 14 is a plan view illustrating a semiconductor optical device according to a fifth embodiment.

FIG. 15A is a diagram illustrating a result of a calculation of a coupling efficiency.

FIG. 15B is a diagram illustrating a result of a calculation of a coupling efficiency.

### DETAILED DESCRIPTION OF EMBODIMENTS

In order to increase a coupling efficiency between an optical waveguide provided on a substrate and an optical waveguide of a group III-V semiconductor element, a tip of the optical waveguide of the group III-V semiconductor element may be tapered. However, it is difficult to reduce a width of the tip of the taper to 400 nm or less by dry etching, for example. Accordingly, it is an object of the present disclosure to provide a semiconductor optical device and a method of manufacturing the same, which are easy to manufacture and capable of improving coupling efficiency.

### Description of Embodiments of the Present Disclosure

First, the contents of the embodiments of the present disclosure will be listed and explained.
(1) A semiconductor optical device according to one aspect of the present disclosure includes a substrate formed of silicon and having a first optical waveguide and a semiconductor element formed of a III-V compound semiconductor and having a second optical waveguide, the semiconductor element being bonded to an upper surface of the substrate. The first optical waveguide and the second optical waveguide form a directional coupler. Since the directional coupler is formed by bringing the first optical waveguide and the second optical waveguide close to each other, it is easy to be manufactured. As the directional coupler is formed, a coupling efficiency can be increased.
(2) In (1), the first optical waveguide may have a bent shape to approach the second optical waveguide. As the first optical waveguide approaches the second optical waveguide, the directional coupler is formed. As the directional coupler is formed, the coupling efficiency can be increased.
(3) In (1) or (2), the first optical waveguide may include a first part and a second part. A distance between the second part and the second optical waveguide may be smaller than a distance between the first part and the second optical waveguide. The second part and the second optical waveguide may form the directional coupler. As the directional coupler is formed, the coupling efficiency can be increased.
(4) In any one of (1) to (3), the second optical waveguide may be positioned above one end portion of the first optical waveguide in a width direction and may not extend to another end portion of the first optical waveguide. As the first optical waveguide and the second optical waveguide form the directional coupler, the coupling efficiency can be increased.
(5) In any one of (1) to (4), in a width direction of each of the first optical waveguide and the second optical waveguide, a center of the second part of the first optical waveguide may be spaced from a center of the second optical waveguide. As the first optical waveguide and the second optical waveguide form the directional coupler, the coupling efficiency may be increased.
(6) In (5), in a direction in which the substrate and the semiconductor element are bonded together, at least a portion of the second part of the first optical waveguide may not overlap the second optical waveguide. As the first optical waveguide and the second optical waveguide form the directional coupler, the coupling efficiency may be increased.
(7) In any one of (3) to (6), a phase adjustment portion may be provided at the first part of the first optical waveguide. The phase of the light can be adjusted.
(8) In any one of (1) to (7), the directional coupler formed by the first optical waveguide and the second optical waveguide may be a plurality of directional couplers, and the plurality of directional couplers may be arranged in an extension direction of each of the first optical waveguide and the second optical waveguide. The coupling efficiency can be increased by the plurality of directional couplers.
(9) In any one of (1) to (8), the semiconductor element may have a first semiconductor layer and a mesa, the first semiconductor layer may be bonded to the upper surface of the substrate, and the mesa may project from the first semiconductor layer toward a direction opposite to the substrate and may have the second optical waveguide. As the first optical waveguide and the second optical waveguide form the directional coupler, the coupling efficiency can be increased.
(10) In (9), the mesa may have a second semiconductor layer, a third semiconductor layer, and a fourth semiconductor layer. The second semiconductor layer, the third semiconductor layer, and the fourth semiconductor layer may be stacked in this order on the first semiconductor layer. The third semiconductor layer may have a multiple quantum well structure. The third semiconductor layer serves as a core of the second optical waveguide, and light can be confined in the third semiconductor layer.
(11) In any one of (1) to (10), the substrate may have a first layer, a second layer, and a third layer stacked in order. The first layer and the third layer may be formed of silicon. The second layer may be formed of silicon oxide. The semiconductor element may be bonded to the third layer. As the first optical waveguide provided in the third layer and the second optical waveguide provided in the semiconductor element form the directional coupler, the coupling efficiency can be increased.
(12) In any one of (1) to (11), the first optical waveguide of the substrate may include two first optical waveguides, and the two first optical waveguides and the second optical waveguide may form the directional coupler. The coupling length between the first optical waveguide and the second optical waveguide can be shortened.
(13) In any one of (1) to (12), the semiconductor element may have an optical gain, and the semiconductor element may function as a laser element. The light generated by the semiconductor element propagates through the second optical waveguide and can be transmitted between the second optical waveguide and the first optical waveguide in the directional coupler.
(14) In any one of (1) to (13), the first optical waveguide may have a tapered portion, the tapered portion may become thinner toward a tip of the first optical waveguide, and the tapered portion of the first optical waveguide and the second optical waveguide may form the directional coupler. The coupling efficiency between the first optical waveguide and the second optical waveguide is increased. Tolerance to dimensional errors is improved.
(15) In (14), the tapered portion of the first optical waveguide may have an asymmetrical shape with respect to a direction in which the first optical waveguide extends. The coupling efficiency between the first optical waveguide and the second optical waveguide is increased. Tolerance to dimensional errors is improved.
(16) In (15), a first end portion of the first optical waveguide may be parallel to the direction in which the first optical waveguide extends, a second end portion of the first optical waveguide may approach the second optical waveguide, and the tapered portion may form the asymmetrical shape. The coupling efficiency between the first optical waveguide and the second optical waveguide is increased. Tolerance to dimensional errors is improved.
(17) In (14), the tapered portion of the first optical waveguide may have a symmetrical shape with respect to a direction in which the first optical waveguide extends. The coupling efficiency between the first optical waveguide and the second optical waveguide is increased. Tolerance to dimensional errors is improved.
(18) A method of manufacturing a semiconductor optical device includes bonding a semiconductor element formed of a III-V compound semiconductor to an upper surface of a substrate formed of silicon and having a first optical waveguide and forming a second optical waveguide at the semiconductor element. The first optical waveguide and the second optical waveguide form a directional coupler. Since the directional coupler is formed by bringing the first optical waveguide and the second optical waveguide close to each other, it is easy to manufacture. As the directional coupler is formed, the coupling efficiency can be increased.

### Details of Embodiments of Present Disclosure

Specific examples of a semiconductor optical device and a method of manufacturing the same according to embodiments of the present disclosure will be described below with reference to the drawings. It should be noted that the present disclosure is not limited to these examples, but is defined by the scope of claims, and is intended to include all modifications within the meaning and range equivalent to the scope of claims.

### First Embodiment

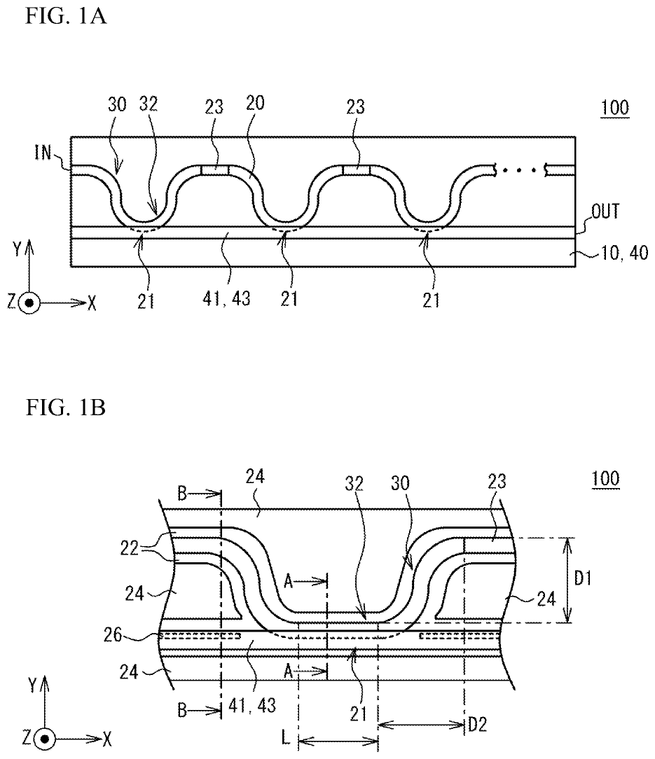

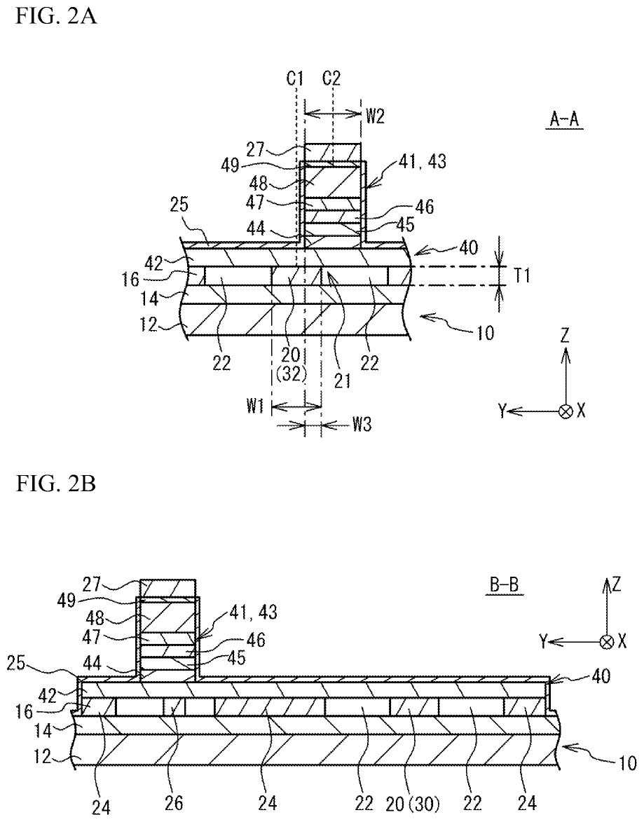

FIG. 1A is a plan view illustrating a semiconductor optical device 100 according to a first embodiment. FIG. 1B is an enlarged plan view of a portion of semiconductor optical device 100. FIG. 2A is a cross-sectional view taken along line A-A of FIG. 1B. FIG. 2B is a cross-sectional view taken along line B-B of FIG. 1B.

As illustrated in FIG. 1A, two sides of semiconductor optical device 100 extend parallel to an X-axis direction. The other two sides extend parallel to a Y-axis direction. A Z-axis direction is a normal direction of a XY plane and is a stacking direction of layers. The X-axis direction, the Y-axis direction and the Z-axis direction are orthogonal to each other. Semiconductor optical device 100 may be a single rectangular chip or may be a rectangular region of a portion of a large chip (such as a wavelength tunable laser) in which a plurality of elements are integrated.

Semiconductor optical device 100 is a hybrid optical element having a substrate 10 and a semiconductor element 40. Substrate 10 has an upper surface parallel to the XY plane. Semiconductor element 40 is bonded to the upper surface of substrate 10. In the plan view, semiconductor element 40 is seen through and the upper surface of substrate 10 is illustrated.

Substrate 10 has an optical waveguide 20 (first optical waveguide). Semiconductor element 40 includes an optical waveguide 41 (second optical waveguide). Optical waveguide 20 and optical waveguide 41 extend from one end portion to another end portion of semiconductor optical device 100 in the X-axis direction.

As illustrated in FIG. 1A, optical waveguide 41 extends, for example, linearly and is parallel to the X-axis direction. Optical waveguide 20 has a wave-like shape in the XY plane and approaches optical waveguide 41 at the antinodes of the wave. The linear part of optical waveguide 20 is parallel to the X-axis direction. Optical waveguide 20 bends and approaches optical waveguide 41. Optical waveguide 20 has a part 30 (first part) far from optical waveguide 41 and a part 32 (second part) close to optical waveguide 41.

As illustrated in FIGS. 1B and 2A, a portion of part 32 of optical waveguide 20 extends below optical waveguide 41 and overlaps optical waveguide 41. In part 32, a distance between optical waveguide 20 and optical waveguide 41 is reduced, and optical waveguide 20 and optical waveguide 41 form a directional coupler (DC) 21. The number of directional coupler 21 may be plural or one. In the first embodiment, the number of directional couplers 21 is plural, for example, three or more, five or more, or the like. The plurality of directional couplers 21 are arranged in the X-axis direction.

A phase adjustment portion 23 is provided in a portion of optical waveguide 20 extending in the X-axis direction. The number of phase adjustment portions 23 may be one or more. In phase adjustment portion 23, a heater having a predetermined length is provided along optical waveguide 20. The heater changes the temperature of phase adjustment portion 23. A refractive index of phase adjustment portion 23 is changed according to the temperature change, and a phase of light passing through phase adjustment portion 23 is changed. The heater is formed of a metal such as tantalum (Ta). A length of phase adjustment portion 23 in the X-axis direction is, for example, 100 μm.

As illustrated in FIGS. 1B and 2A, substrate 10 has optical waveguide 20, grooves 22, and a terrace 24. Grooves 22 are positioned on both sides of optical waveguide 20 and extend along optical waveguide 20. As illustrated in FIG. 1B, optical waveguide 20 has a wave-like plane. A support body 26 is linear and parallel to the X-axis direction. Support body 26 is formed from a silicon(Si) layer 16 and is positioned away from optical waveguide 20. Terrace 24 is a portion of Si layer 16 extending in a planar manner.

As illustrated in FIGS. 2A and 2B, substrate 10 is an SOI substrate having a substrate 12 (first layer), a box layer 14 (second layer), and silicon (Si) layer 16 (third layer). Substrate 12 is formed of Si having a thickness of 500 μm, for example. Box layer 14 is formed of silicon oxide (SiO₂) having a thickness of 3 μm, for example, and is stacked on an upper surface of substrate 12. Si layer 16 is formed of Si having a thickness of 220 nm, for example, and is stacked on an upper surface of box layer 14.

Each groove 22 is a portion of Si layer 16 that is recessed in the Z-axis direction from the upper surface, and is formed by etching Si layer 16, for example. In the Z-axis direction, groove 22 may extend to the middle of Si layer 16 or may penetrate Si layer 16 and extend to box layer 14. That is, the depth of groove 22 is 220 nm (the thickness of Si layer 16) or less. Refractive indices of substrate 12 and Si layer 16 are 3.48 at a wavelength of 1.55 μm, for example. A refractive index of box layer 14 is lower than the refractive indices of substrate 12 and Si layer 16, and is 1.44 at the wavelength of 1.55 μm, for example.

Optical waveguide 20, terrace 24, and support body 26 are formed in Si layer 16 and are portions that project in the Z-axis direction from the bottom surface of groove 22. In the etching process for forming groove 22, the unetched portions become optical waveguide 20, terrace 24, and support body 26. The upper surface of each of optical waveguide 20, terrace 24, and support body 26 is parallel to the XY plane and forms one plane, i.e., the upper surface of substrate 10. A thickness T1 of optical waveguide 20 illustrated in FIG. 2A is equal to the depth of groove 22, for example, 220 nm. A width W1 of optical waveguide 20 is, for example, 880 nm.

Semiconductor element 40 includes a bonding layer 42 (first semiconductor layer), cladding layers 44 and 48, optical confinement layers 45 and 47, an active layer 46 (third semiconductor layer), and a contact layer 49. Bonding layer 42 covers the upper surface of Si layer 16 of substrate 10 and is bonded to the upper surface. Bonding layer 42 may be in contact with the upper surface of Si layer 16, or another layer may be provided between bonding layer 42 and Si layer 16.

Semiconductor element 40 includes a mesa 43. As described in the third embodiment, mesa 43 is formed in semiconductor element 40 by bonding semiconductor element 40 to substrate 10 and etching semiconductor element 40. Mesa 43 projects from the upper surface of Si layer 16 in the Z-axis direction. Mesa 43 includes cladding layers 44 and 48, optical confinement layers 45 and 47, active layer 46, and contact layer 49. On bonding layer 42, cladding layer 44 (second semiconductor layer), optical confinement layer 45, active layer 46, optical confinement layer 47, cladding layer 48 (fourth semiconductor layer), and contact layer 49 are stacked in this order in the Z-axis direction. Mesa 43 extends parallel to the X-axis direction from one end portion to another end portion of substrate 10 in the X-axis direction, and functions as optical waveguide 41. Active layer 46 serves as a core layer of optical waveguide 41.

As illustrated in FIGS. 2A and 2B, bonding layer 42 of semiconductor element 40 is bonded to terrace 24 of substrate 10 and supported by terrace 24. In the region illustrated in FIG. 1B, a central portion of mesa 43 of semiconductor element 40 in the X-axis direction (a portion adjacent to part 32 of the optical waveguide 20) is positioned to overlap optical waveguide 20, and portions on both sides thereof in the X-axis direction are positioned to overlap support body 26. Mesa 43 is supported by support body 26.

An electrically insulating film 25 covers side surfaces of mesa 43 and the upper surface of bonding layer 42. Electrically insulating film 25 is formed of an insulating material such as silicon nitride (SiN), silicon oxide (SiO₂), or silicon oxynitride (SiON). A thickness of electrically insulating film 25 is, for example, 100 nm to 600 nm. Electrically insulating film 25 has an opening portion on the upper surface of mesa 43. An electrode 27 is provided on the upper surface of contact layer 49. Electrode 27 is formed of a metal such as gold (Au).

Bonding layer 42 is formed of, for example, indium phosphide (InP) having a thickness of 182 nm. Cladding layer 44 is formed of, for example, n-type indium phosphide (n-InP) having a thickness of 180 nm. For example, Si is used as the n-type dopant. Cladding layer 48 is formed of, for example, p-type indium phosphide (p-InP) having a thickness of 1700 nm. A refractive index of each of bonding layer 42 and cladding layers 44 and 48 is lower than a refractive index of active layer 46, and is 3.17 at the wavelength of 1.55 μm, for example. Contact layer 49 is formed of, for example, p+-type gallium indium arsenide ((p+)-GaInAs). For example, zinc (Zn) is used as the p-type dopant.

Active layer 46 has a multi quantum well (MQW) structure, and includes a plurality of well layers and a plurality of barrier layers. The plurality of well layers and the plurality of barrier layers are alternately stacked. One well layer is formed of, for example, GaInAsP having a thickness of 6 nm. One barrier layer is formed of, for example, GaInAsP having a thickness of 10 nm. Active layer 46 has, for example, a thickness of 90 nm. The refractive index of active layer 46 is, for example, 3.44 at the wavelength of 1.55 μm.

Optical confinement layers 45 and 47 are formed of, for example, undoped gallium indium arsenide phosphide (i-GaInAsP). Optical confinement layer 45 has, for example, a thickness of 80 nm. Optical confinement layer 47 has, for example, a thickness of 100 nm. A band gap wavelength of each of optical confinement layers 45 and 47 is, for example, 1.2 μm, which is shorter than a wavelength of light input to and output from semiconductor optical device 100. A refractive indexes of each of optical confinement layers 45 and 47 is, for example, 3.34 at the wavelength of 1.55 μm. Each of the semiconductor layers of semiconductor element 40 is formed of a III-V compound semiconductor, and may be formed of a semiconductor other than the above.

A width W2 of mesa 43 is, for example, 500 nm, 550 nm, 600 nm, or the like, and is several hundred nm. A distance between mesa 43 and part 30 of optical waveguide 20 is greater than a distance between mesa 43 and part 32 of optical waveguide 20. A distance D1 in the Y-axis direction between phase adjustment portion 23 and part 32 of optical waveguide 20 illustrated in FIG. 1B is, for example, 0.9 μm. Part 32 of optical waveguide 20 extends below mesa 43. A width direction of the optical waveguide is perpendicular to an extending direction of the optical waveguide. In FIG. 1B, the width direction is parallel to the Y-axis direction. In part 32 of optical waveguide 20, mesa 43 is positioned on one end portion in the width direction of optical waveguide 20 and does not extend to another end portion in the width direction of optical waveguide 20. That is, one end portion of optical waveguide 20 is positioned below mesa 43 and another end portion is positioned outside optical waveguide 20. Mesa 43 and a portion of part 32 of optical waveguide 20 overlap when viewed in the Z-axis direction. A width W3 (overlap amount, see FIG. 2A) of the overlapping portion is, for example, 300 nm to 400 nm, and is several hundred nm.

A line C1 in FIG. 2A represents the center of optical waveguide 20 in the Y-axis direction. A line C2 represents the center of optical waveguide 41 in the Y-axis direction. The center of optical waveguide 20 and the center of optical waveguide 41 do not overlap and are spaced apart from each other.

Semiconductor element 40 and substrate 10 are evanescently optically coupled with each other. Part 32 of optical waveguide 20 and optical waveguide 41 of semiconductor element 40 form directional coupler 21 and are optically coupled to each other. A coupling length L in one directional coupler 21 illustrated in FIG. 1B, that is, the length of the part in which optical waveguide 20 and optical waveguide 41 extend in parallel overlapping each other, is, for example, 50 A distance D2 from a coupling portion to phase adjustment portion 23 is, for example, 20 μm.

For example, one end portion of optical waveguide 20 in the extending direction is referred to as an incident port IN, and one end portion of optical waveguide 41 in the extending direction is referred to as an exit port OUT. Light is made incident on incident port IN of optical waveguide 20. Light propagates through optical waveguide 20 and transmits from optical waveguide 20 to optical waveguide 41 in directional coupler 21. Light transmitted to optical waveguide 41 is emitted from the end portion of optical waveguide 41. By the heater of phase adjustment portion 23 provided in optical waveguide 20, the refractive index of optical waveguide 20 is changed. By changing the refractive index, the phase of light can be adjusted and phase matching can be performed. Semiconductor optical device 100 functions as a Mach-Zehnder interferometer. When a voltage is applied to electrode 27 provided in optical waveguide 41, optical waveguide 41 has an optical gain.

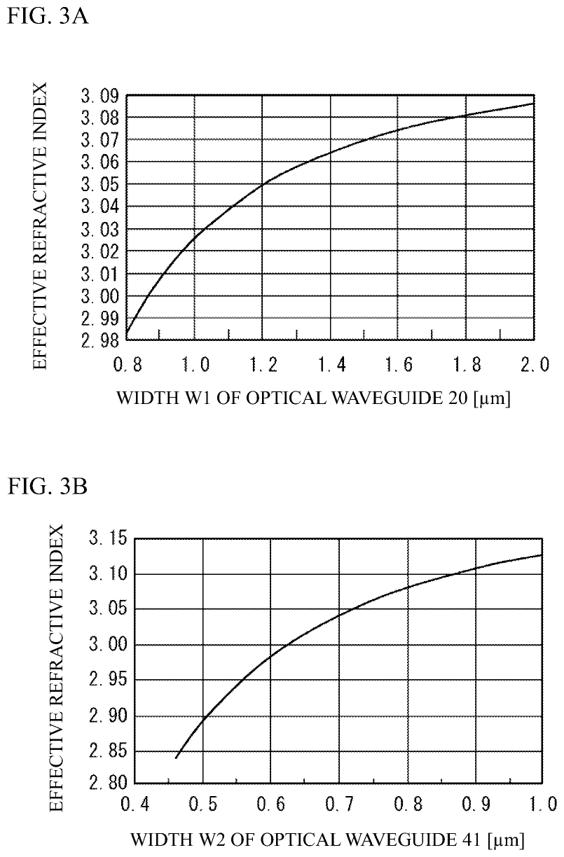

FIGS. 3A and 3B are diagrams illustrating effective refractive indices. The horizontal axis represents a width of an optical waveguide. The vertical axis represents the effective refractive index of the optical waveguide at the wavelength of 1.55 μm.

FIG. 3A is diagram illustrating the effective refractive index of optical waveguide 20. FIG. 3B is diagram illustrating the effective refractive index of optical waveguide 41. As illustrated in each of FIGS. 3A and 3B, the effective refractive index increases as the width of the optical waveguide increases. Preferably, the widths of optical waveguides 20 and 41 are adjusted so that the effective refractive index of optical waveguide 20 and the effective refractive index of optical waveguide 41 are of similar magnitude. When the effective refractive indices of the two waveguides are substantially equal to each other, the coupling efficiency between optical waveguide 20 and optical waveguide 41 can be increased in directional coupler 21.

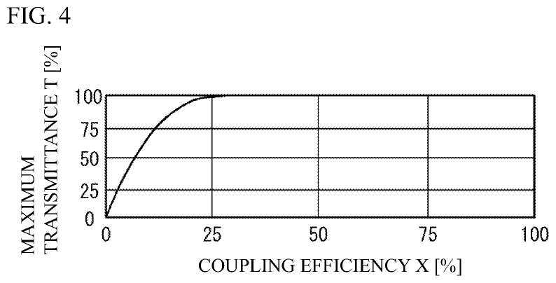

FIG. 4 is a diagram illustrating a transmittance, and illustrates a calculated transmittance of light from optical waveguide 20 to optical waveguide 41. The horizontal axis represents a coupling efficiency X in one directional coupler 21. The vertical axis represents a transmittance T (maximum transmittance) of light from optical waveguide 20 to optical waveguide 41 when light having a wavelength of 1.55 μm is guided. The number of directional couplers 21 is three. Coupling efficiencies X of three directional couplers 21 are assumed to be equal to each other.

Coupling efficiency X is designed by adjusting the effective refractive index, coupling length L, and an overlap amount W3 of optical waveguide 20 and optical waveguide 41. Transmittance T is expressed by the following equation as a function of coupling efficiency X.

T=16X³−24X²+9X

The range of coupling efficiency X over which maximum transmittance T=100% can be achieved is expressed by the following equations. Note that, in the following equation, X is treated with 100% as 1.
When n is an odd number, 1≥X≥sin²(π/(2n)),
When n is an even number, 1−sin²(π/(2n))≥X≥sin²(π/(2n)),
where n is the number of directional couplers 21, and n=3 in the example of FIG. 4.
When specific numerical values are input to the above two equations, X (%) is as follows.
When n=1, X=100%.
When n=2, X=50%.
When n=3, 100%≥X≥25%.
When n=4, 85.35%≥X≥14.64%.
When n=5, 100%≥X≥9.54%.
When n=6, 93.30%≥X≥6.69%.
That is, when n is set to 3 or more, the range of coupling ratio X in which transmittance T can be 100% is wider when n is an odd number rather than an even number. As illustrated in FIG. 4, in the case of n=3, when coupling efficiency X becomes 25% or more, transmittance T becomes 100%. That is, light can be incident on optical waveguide 20 and all of the light can be emitted from optical waveguide 41.

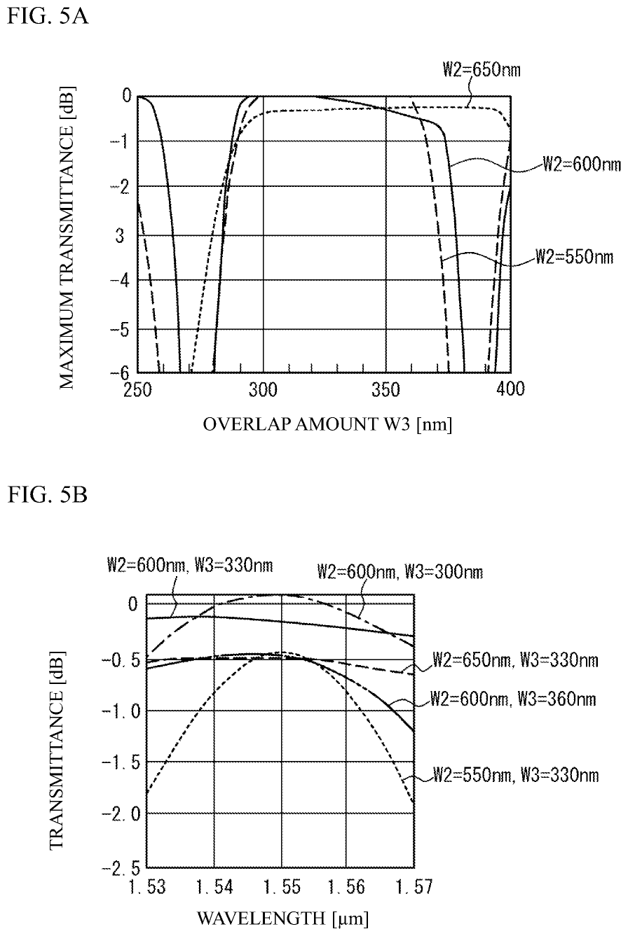

FIG. 5A is diagram illustrating a dependence of the transmittance on the overlap amount. The horizontal axis represents overlap amount W3. The vertical axis represents the maximum transmittance from optical waveguide 20 to optical waveguide 41. The transmittance was calculated using the wavelength of light as 1550 nm and overlap amount W3 as a variable.

The dashed line in FIG. 5A is an example in which width W2 of optical waveguide 41 is 550 nm. The solid line is an example in which width W2 is 600 nm. The dotted line is an example in which width W2 is 650 nm. In all three examples, the optical loss can be suppressed to less than 1 dB when overlap amount W3 is in the range of 290 nm to 360 nm.

FIG. 5B is a graph illustrating a wavelength dependence of transmittance. The horizontal axis represents the wavelength of light. The vertical axis represents the transmittance. In the example of the solid line, width W2 of optical waveguide 41 is 600 nm, and overlap amount W3 is 330 nm. In the example of the dashed line, width W2 is 650 nm and overlap amount W3 is 330 nm. In the example of the dotted line, width W2 is 550 nm, and overlap amount W3 is 330 nm. In the example of the one dot chain line, width W2 is 600 nm, and overlap amount W3 is 300 nm. In the example of the two dot chain line, width W2 is 600 nm, and overlap amount W3 is 360 nm. In the entire C-band (from 1530 nm to 1565 nm), the optical loss is suppressed to less than 1.8 dB.

Variations occur in width W1 of optical waveguide 20, width W2 of optical waveguide 41, and overlap amount W3 due to deviations of the resist patterns in the manufacturing process. As illustrated in FIG. 5A, when width W2 of mesa 43 is within the range of 600±50 nm and overlap amount W3 is within the range of 290 nm to 360 nm, for example, the optical loss is suppressed to less than 1 dB. As illustrated in FIG. 5B, when width W2 of optical waveguide 41 is in the range of 600±50 nm and overlap amount W3 is from 300 nm to 330 nm, the optical loss is suppressed to less than 1.8 dB over the entire C-band.

According to the first embodiment, substrate 10 has optical waveguide 20 formed of Si. Semiconductor element 40 is bonded to the upper surface of substrate 10 and includes optical waveguide 41 formed of a III-V compound semiconductor. Since optical waveguide 20 and optical waveguide 41 form directional coupler 21, high coupling efficiency can be obtained. Light passes between optical waveguide 20 and optical waveguide 41 at directional coupler 21. As illustrated in FIGS. 5A and 5B, it is possible to suppress optical loss and propagate light in two optical waveguides.

The coupling efficiency can be increased by providing optical waveguide 41 with a narrow taper having a width of several hundred nm or less, for example. However, it is difficult to form a taper by etching with a high aspect ratio (high ratio of thickness to width). According to the first embodiment, optical waveguide 41 may not be tapered. As optical waveguide 20 and optical waveguide 41 approaches to each other, directional coupler 21 is formed, and the coupling efficiency can be increased.

As illustrated in FIGS. 1A and 1B, optical waveguide 20 has a wave-like plane and bends toward optical waveguide 41. As optical waveguide 20 approaches optical waveguide 41, directional coupler 21 is formed.

Specifically, optical waveguide 20 has part 30 and part 32. The distance between part 32 and optical waveguide 41 is smaller than the distance between part 30 and optical waveguide 41. Since part 32 is close to optical waveguide 41, directional coupler 21 is formed. Wavy optical waveguide 20 is formed in Si layer 16 by, for example, etching. Mesa 43 is formed by etching at a position close to optical waveguide 20 in semiconductor element 40. Semiconductor optical device 100 having directional coupler 21 can be manufactured by a simple process.

As illustrated in FIG. 2A, the center (line C1) of part 32 of optical waveguide 20 is spaced apart from the center (line C2) of optical waveguide 41. That is, optical waveguide 20 is spaced apart from optical waveguide 41 in the width direction (Y-axis direction) and is also spaced apart from optical waveguide 41 in the thickness direction (Z-axis direction). In other words, in a plane parallel to a YZ plane, optical waveguide 20 and optical waveguide 41 are disposed obliquely to each other. Optical waveguide 20 and optical waveguide 41 which are obliquely disposed form directional coupler 21. It is possible to increase the coupling efficiency and be transmitted light between the two optical waveguides.

For example, as illustrated in FIG. 2A, in the width direction (Y-axis direction), optical waveguide 41 is positioned above one end portion of optical waveguide 20 and does not extend to another end portion. That is, seen from the Z-axis direction, a portion of optical waveguide 20 overlaps optical waveguide 41, and the other portion does not overlap optical waveguide 41. With respect to width W1 (880 nm or the like) of optical waveguide 20, overlap amount W3 between optical waveguide 20 and optical waveguide 41 is, for example, 300 nm±30 nm or the like. Overlap amount W3 may be equal to or less than half of width W1, or may be equal to or more than half of width W1.

Bonding layer 42 of semiconductor element 40 is bonded to the upper surface of substrate 10. Mesa 43 projects from bonding layer 42 in the Z-axis direction and has optical waveguide 41. Optical waveguide 41 is positioned above substrate 10. Optical waveguide 20 and optical waveguide 41 which are obliquely disposed form directional coupler 21. It is possible to increase the coupling efficiency and be transmitted light between the two optical waveguides.

In mesa 43, cladding layer 44, optical confinement layer 45, active layer 46, optical confinement layer 47, cladding layer 48, and contact layer 49 are stacked in this order. Active layer 46 has the multiple quantum well structure, and functions as the core layer of optical waveguide 41. Active layer 46 is sandwiched between cladding layers 44 and 48. Light can be confined in active layer 46 and loss can be suppressed.

Substrate 10 is the SOI substrate and includes substrate 12, box layer 14, and Si layer 16. Optical waveguide 20 is provided in Si layer 16. Optical waveguide 20 of Si and optical waveguide 41 of the III-V compound semiconductor form directional coupler 21, so that the coupling efficiency can be increased.

As illustrated in FIGS. 1B and 2B, substrate 10 has support body 26. Support body 26 is spaced apart from optical waveguide 20, is positioned under mesa 43, extends in the same direction (X-axis direction) as mesa 43, and supports mesa 43. The mechanical strength of semiconductor optical device 100 is improved. Preferably, a width of support body 26 is less than width W1 of optical waveguide 20, and is 100 nm or less, for example. Since support body 26 is thin, an effective refractive index of support body 26 is lower than the effective refractive indices of optical waveguides 20 and 41. Light is less likely to spread to support body 26. Support body 26 may not be provided on substrate 10, and mesa 43 may be provided above groove 22 of substrate 10. The optical loss can be suppressed.

For example, by providing terrace 24 under mesa 43, the mechanical strength can be increased. However, since the discontinuity of the refractive index is large between directional coupler 21 and terrace 24, the optical loss may increase. By disposing mesa 43 on support body 26, it is possible to increase the mechanical strength and reduce the discontinuity of the refractive index.

As illustrated in FIG. 1A, semiconductor optical device 100 includes a plurality of directional couplers 21. Since the plurality of directional couplers 21 are arranged along the X-axis direction, coupling efficiency between optical waveguide 20 and optical waveguide 41 is increased. The number of directional couplers 21 is, for example, three or more, five or more, or the like, and is preferably an odd number.

Phase adjustment portion 23 is provided in part 30 of optical waveguide 20. When the heater provided in phase adjustment portion 23 generates heat, the temperature of phase adjustment portion 23 changes, and the refractive index of optical waveguide 20 changes. The phase of the light propagating through optical waveguide 20 can be adjusted. Light can be generated in active layer 46 by applying a current to mesa 43 using an electrode provided on mesa 43. The generated light is optically coupled from optical waveguide 41 to optical waveguide 20 in directional coupler 21. The phase of the light transferred to optical waveguide 20 is adjusted by phase adjustment portion 23, so that the light can be optically coupled to optical waveguide 41 with high coupling efficiency in next directional coupler 21. It is also possible to change the refractive index of optical waveguide 41 by using electrode 27 provided on mesa 43. The coupling efficiency can be increased by making the effective refractive index of optical waveguide 20 and the effective refractive index of optical waveguide 41 substantially equal to each other.

### Modification

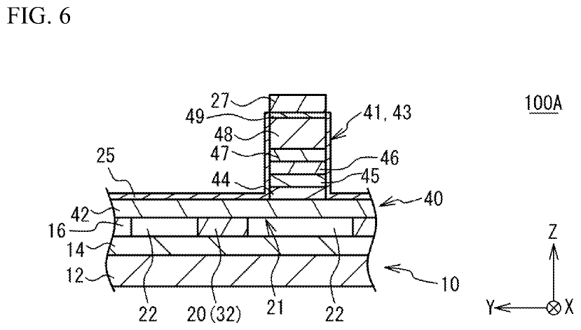

FIG. 6 is a cross-sectional view illustrating a semiconductor optical device 100A according to a modification, and illustrates a cross-section corresponding to FIG. 2A. In the example of FIG. 6, entire optical waveguide 41 does not overlap optical waveguide 20. In other words, the overlap amount is 0. The distance between optical waveguide 20 and optical waveguide 41 in the Y-axis direction is, for example, about 500 nm. Directional coupler 21 is formed by bringing optical waveguide 20 and optical waveguide 41 close to each other.

As illustrated in FIGS. 2A and 6, at least a portion of edges of optical waveguide 20 does not overlap optical waveguide 41 in the plan view in which semiconductor element 40 is seen through. Optical waveguide 20 and optical waveguide 41 come close to each other to form directional coupler 21.

### Second Embodiment

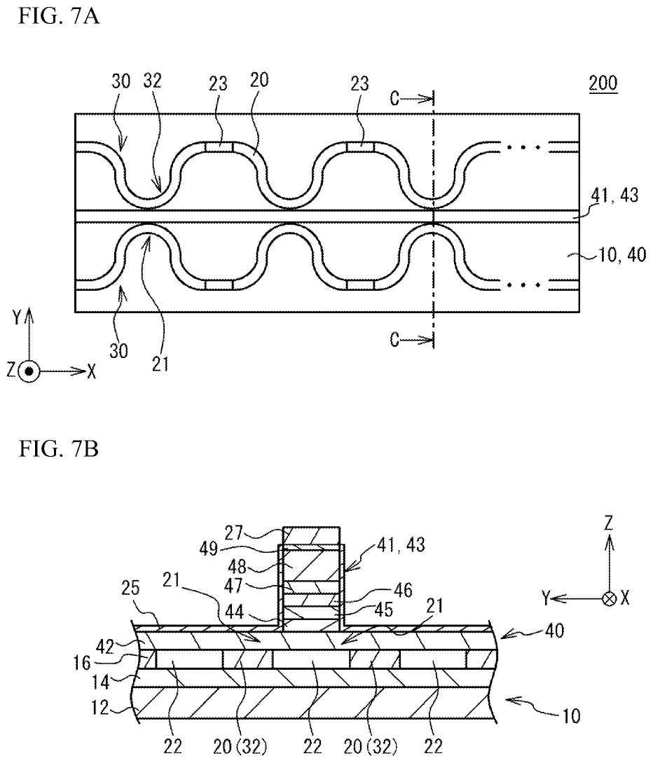

FIG. 7A is a plan view illustrating a semiconductor optical device 200 according to a second embodiment. FIG. 7B is a cross-sectional view taken along line C-C of FIG. 7A. Description of the same configuration as that of the first embodiment will be omitted.

As illustrated in FIGS. 7A and 7B, substrate 10 has two optical waveguides 20. Two optical waveguides 20 are line-symmetric with respect to an axis (an axis parallel to the X-axis) extending along the center of the width direction of optical waveguide 41. Each of two optical waveguides 20 and optical waveguide 41 form directional coupler 21.

According to the second embodiment, since two optical waveguides 20 and optical waveguide 41 form directional coupler 21, the coupling efficiency can be increased. By providing two optical waveguides 20, the coupling length (length L in FIG. 1B) between the optical waveguides can be increased by 1/(√2) times as compared with the case where one optical waveguide 20 is provided.

In the example of FIG. 7B, two optical waveguides 20 do not overlap optical waveguide 41. Portions of two optical waveguides 20 may overlap optical waveguide 41 in the width direction, but the two optical waveguides 20 do not entirely overlap the optical waveguide 41.

### Third Embodiment

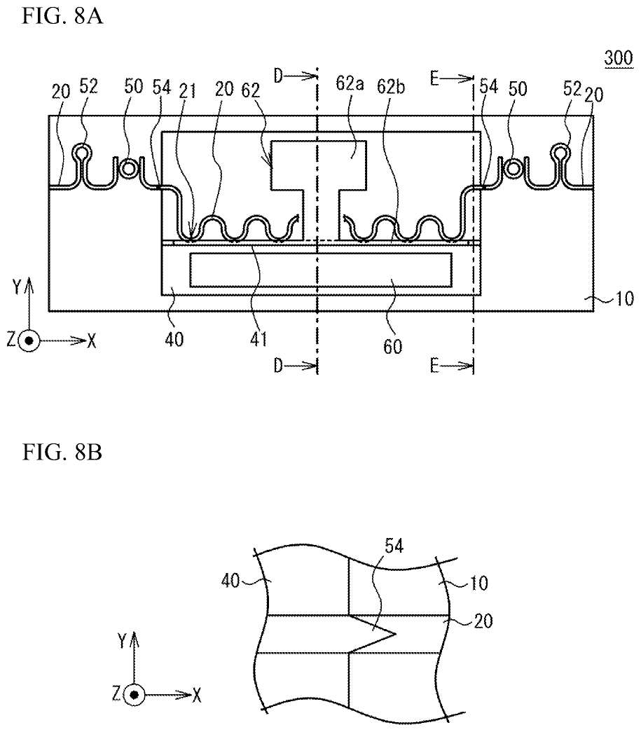

FIG. 8A is a plan view illustrating a semiconductor optical device 300 according to a third embodiment. FIG. 8B is an enlarged plan view of a portion of semiconductor optical device 300. Description of the same configuration as that of the first embodiment will be omitted.

As illustrated in FIG. 8A, substrate 10 has optical waveguide 20, two ring resonators 50 and two loop mirrors 52. Optical waveguide 20 extends from one end portion to another end portion of substrate 10 in the X-axis direction. Two ring resonators 50 and two loop mirrors 52 are provided in the middle of optical waveguide 20. Similarly to optical waveguide 20, ring resonator 50 and loop mirror 52 are provided in Si layer 16 of substrate 10 and have Si cores.

Semiconductor element 40 is bonded to the center of the upper surface of substrate 10. Optical waveguide 41 of semiconductor element 40 and optical waveguide 20 of substrate 10 form a plurality of directional couplers 21. portions of optical waveguide 20 other than directional couplers 21 are spaced apart from optical waveguide 41. The end portion of semiconductor element 40 is spaced apart from the end portion of substrate 10.

As illustrated in FIG. 8B, semiconductor element 40 has a tapered portions 54 at both ends in the X-axis direction. Tapered portion 54 is spaced apart from optical waveguide 41 and positioned above optical waveguide 20. Tapered portion 54 protrudes toward the outside of semiconductor element 40, and has a tapered shape that becomes narrower as it goes away from semiconductor element 40.

As illustrated in FIG. 8A, ring resonator 50 and loop mirror 52 are spaced apart from semiconductor element 40 in the X-axis direction. One ring resonator 50 and one loop mirror 52 are arranged in this order from one end portion of semiconductor element 40 toward one end portion of substrate 10. One ring resonator 50 and one loop mirror 52 are arranged in this order from the other end portion of semiconductor element 40 toward the other end portion of substrate 10. Ring resonator 50 and loop mirror 52 are optically coupled to optical waveguide 20.

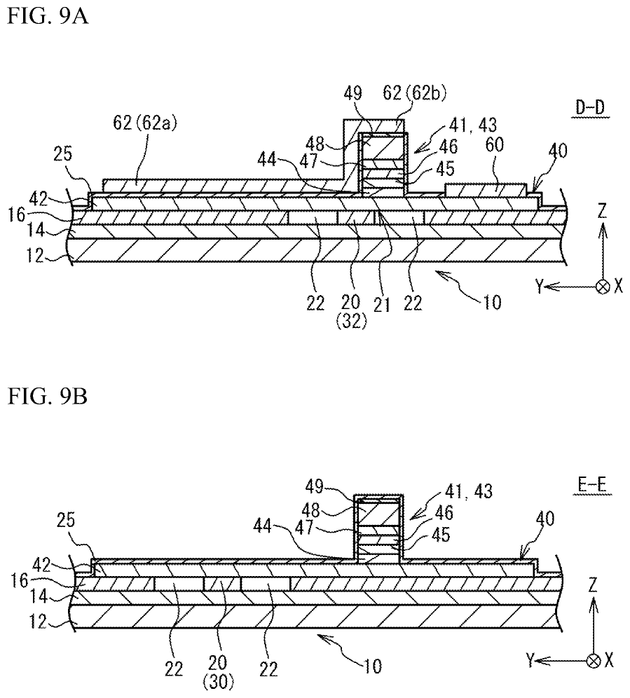

FIG. 9A is a cross-sectional view taken along line D-D of FIG. 8A, illustrating a cross-section including directional coupler 21. As illustrated in FIGS. 8A and 9A, optical waveguide 20 and optical waveguide 41 overlap. Semiconductor element 40 has electrodes 60 and 62. Electrode 60 and electrode 62 are spaced from each other.

As illustrated in FIG. 9A, electrically insulating film 25 has an opening portion on bonding layer 42 and an opening portion on mesa 43. Electrode 60 is an n-type electrode, is disposed on the opening portion of electrically insulating film 25, is in contact with bonding layer 42, and is electrically connected to bonding layer 42. Electrode 62 is a p-type electrode and includes a pad 62a and a connection portion 62b. Pad 62a and connection portion 62b are formed of a metal layer and are electrically connected to each other. Pad 62a is spaced apart from optical waveguide 41 and is provided on electrically insulating film 25. Connection portion 62b is disposed on mesa 43 and is in contact with contact layer 49 through the opening portion of electrically insulating film 25 to be electrically connected to contact layer 49.

Electrode 60 is formed of, for example, an alloy of gold, germanium, and Ni (AuGeNi). Electrode 62 is formed of, for example, a stacked body of titanium, platinum, and gold (Ti/Pt/Au). Electrodes 60 and 62 further include a wiring layer of gold (Au).

FIG. 9B is a cross-sectional view taken along line E-E of FIG. 8A, illustrating a cross-section including a tip of mesa 43 and not including directional coupler 21. As illustrated in FIG. 9B, optical waveguide 20 and optical waveguide 41 are spaced apart. Electrode 62 is not provided on the tip of mesa 43, and is covered with electrically insulating film 25. Tapered portion 54 is formed from bonding layer 42. Tapered portion 54 does not include optical confinement layer 45, active layer 46, optical confinement layer 47, cladding layer 48, or contact layer 49. Therefore, an aspect ratio of etching when forming tapered portion 54 can be suppressed to be low.

Semiconductor element 40 has an optical gain and is evanescently coupled to substrate 10. By applying a voltage to semiconductor element 40 using electrode 60 and electrode 62, a current flows through mesa 43. By injecting carriers into active layer 46, active layer 46 generates light. In directional coupler 21, the light transmits from optical waveguide 41 of semiconductor element 40 to optical waveguide 20 of substrate 10.

The light propagating through optical waveguide 20 is reflected by loop mirror 52. The light is repeatedly reflected by two loop mirrors 52 to cause laser oscillation. The laser light is emitted to the outside of semiconductor optical device 300.

### Method of Manufacturing

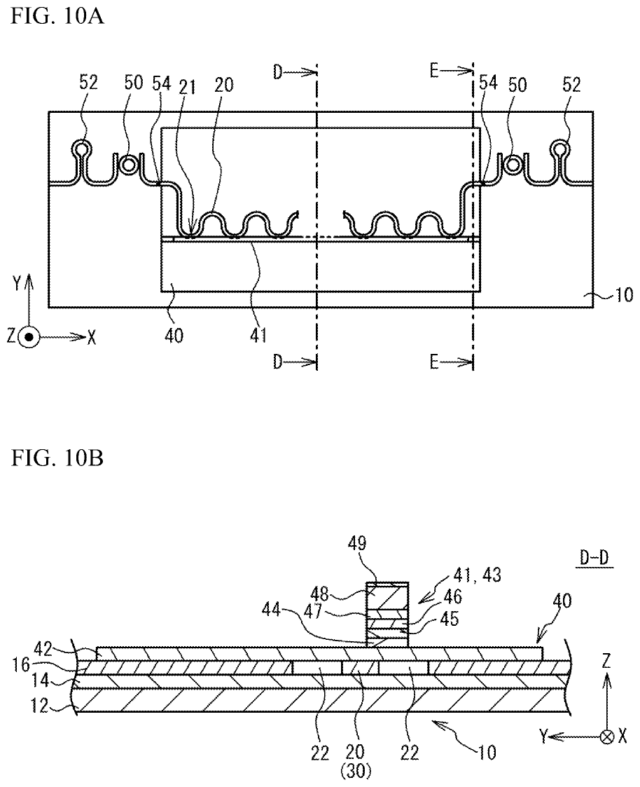

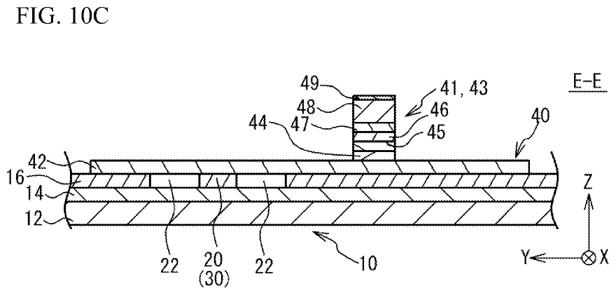

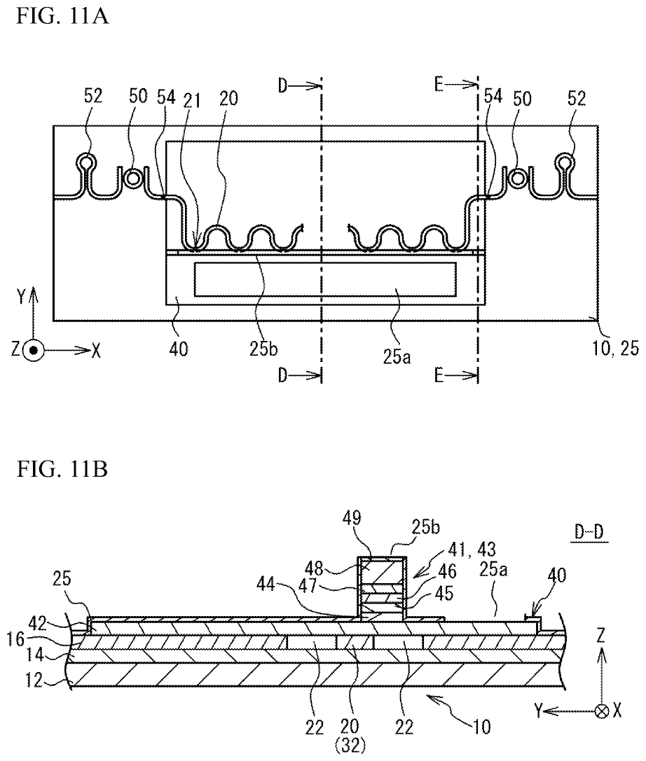

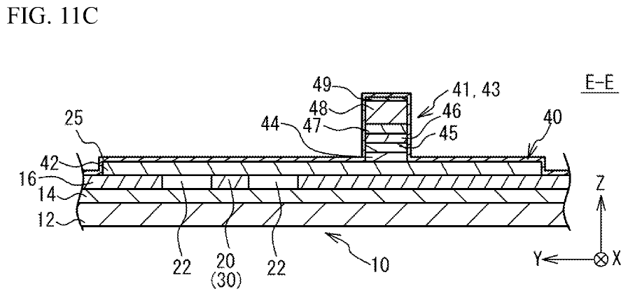

FIGS. 10A, 11A and 12A are plan views illustrating a method of manufacturing semiconductor optical device 300. FIGS. 10B, 11B and 12B are cross-sectional views along line D-D of the corresponding plan views. FIGS. 10C and 11C are cross-sectional views taken along line E-E of the corresponding plan views.

Before the steps illustrated in FIGS. 10A to 10C, dry etching is performed on Si layer 16 of substrate 10 to form grooves 22. Optical waveguide 20, terrace 24, ring resonator 50 and loop mirror 52 are formed in the non-etched portion. For example, bonding layer 42, cladding layer 44, optical confinement layer 45, active layer 46, optical confinement layer 47, cladding layer 48, and contact layer 49 are epitaxially grown on a III-V compound semiconductor wafer by an organometallic vapor phase epitaxy (OMVPE) or the like. Semiconductor element 40 is formed by dicing the wafer. Mesa 43 and the electrode are not formed on semiconductor element 40.

As illustrated in FIGS. 10A to 10C, semiconductor element 40 is bonded to substrate 10. Specifically, Nitrogen (N₂) plasma treatment is performed on the upper surface of Si layer 16 of substrate 10 (i.e., the upper surface of substrate 10) and the surface of bonding layer 42 of semiconductor element 40 to activate. The activated surfaces are ultrasonically cleaned in water. The activated surfaces are brought into contact with each other, and semiconductor element 40 is temporarily bonded to the upper surface of substrate 10. After the temporary bonding, annealing is performed, for example, at 300° C. for 2 hours to remove moisture and strengthen the bonding strength (O₂ binding). Two ring resonators 50 and two loop mirrors 52 are positioned outside semiconductor element 40. The wave-shaped portion of optical waveguide 20 is covered with semiconductor element 40.

An electrically insulating film serving as an etching mask is formed on substrate 10 and semiconductor element 40. A resist pattern is formed on the electrically insulating film by photolithography or the like, and the pattern is transferred to the electrically insulating film by etching (an etching mask and a resist pattern are not illustrated). Etching is performed using the etching mask. For example, RIE using a mixture gas of methane and hydrogen (CH₄/H₂) or a chlorine-based gas and wet etching are performed to form mesa 43 in semiconductor element 40. In the portions other than mesa 43, bonding layer 42 is exposed. The electrically insulating film used as the mask is removed by wet etching using a buffered hydrogen fluoride (BHF). Bonding layer 42 is then etched to form tapered portion 54. Since tapered portion 54 does not include optical confinement layer 45, active layer 46, optical confinement layer 47, cladding layer 48, or contact layer 49, the aspect ratio of etching when tapered portion 54 is formed is low. Therefore, the shape of the narrow tip of tapered portion 54 can be formed with high accuracy.

As illustrated in FIGS. 11A to 11C, electrically insulating film 25 is formed by, for example, a chemical vapor deposition (CVD) method. Electrically insulating film 25 covers substrate 10 and semiconductor element 40. An opening portion is formed in electrically insulating film 25 by wet etching, for example. As illustrated in FIG. 11B, one opening portion 25a is provided at a position spaced apart from mesa 43 and one opening portion 25b is formed above mesa 43.

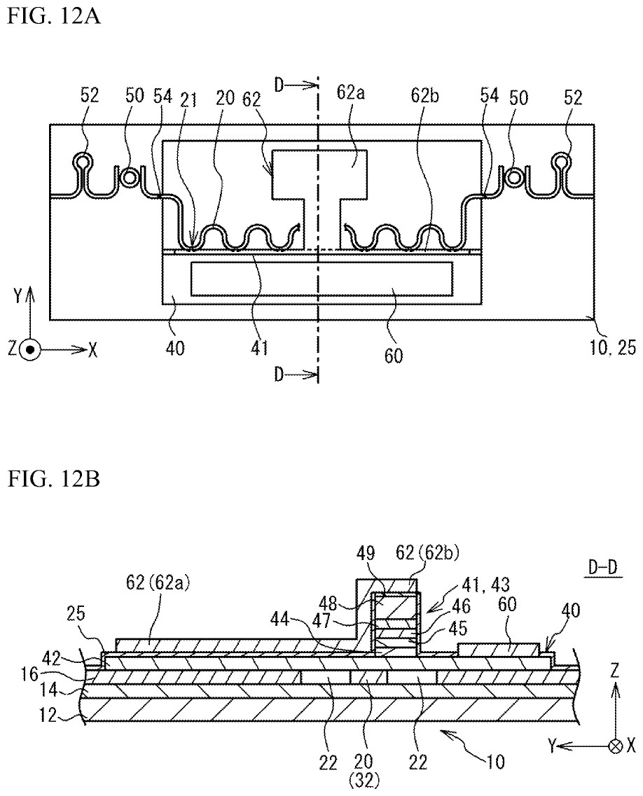

As illustrated in FIGS. 12A and 12B, electrodes 60 and 62 are formed, for example, by vacuum deposition and lift-off. A wiring layer of Au may be formed by plating, for example. Semiconductor optical device 300 is formed by dicing substrate 10 which is in a wafer state before dicing.

According to the third embodiment, semiconductor optical device 300 functions as a laser element. Semiconductor element 40 having an optical gain generates light. Since optical waveguide 41 of semiconductor element 40 and optical waveguide 20 of substrate 10 form directional coupler 21, light is transmitted between the two optical waveguides. The light propagates through optical waveguide 20, is reflected by two loop mirrors 52, and causes laser oscillation. Semiconductor optical device 300 can emit laser light from the end portion of substrate 10 toward the outside.

In semiconductor optical device 300, as illustrated in FIG. 6, optical waveguide 20 and optical waveguide 41 may be spaced from each other. Two optical waveguides 20 may be provided. An optical element other than ring resonator 50 and loop mirror 52 may be provided on substrate 10.

### Fourth Embodiment

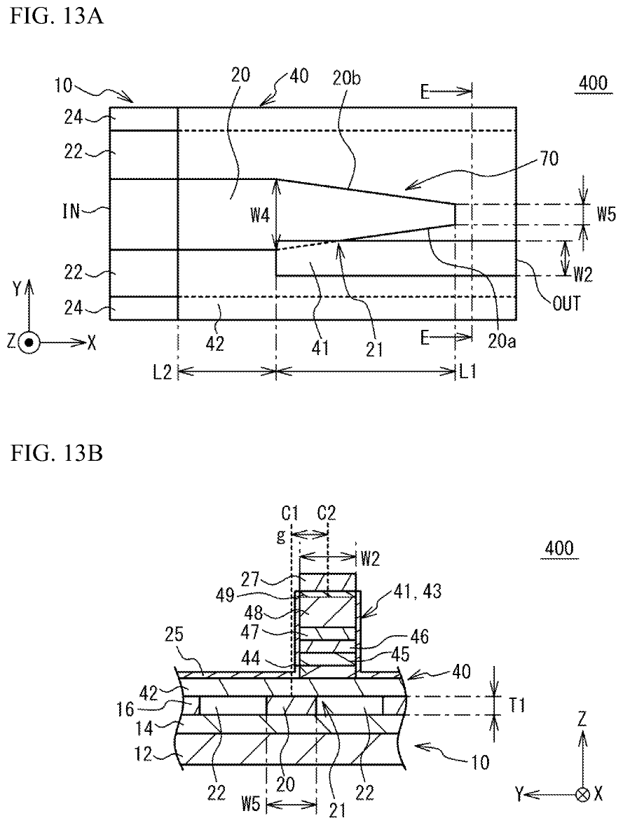

FIG. 13A is a plan view illustrating a semiconductor optical device 400 according to a fourth embodiment. FIG. 13B is a cross-sectional view taken along line E-E of FIG. 13A. A description of the same configuration as any one of the first embodiment to the third embodiment will be omitted. As illustrated in FIG. 13A, semiconductor optical device 400 includes optical waveguide 20 and optical waveguide 41. Optical waveguide 20 and optical waveguide 41 form one directional coupler 21.

Optical waveguide 20 and optical waveguide 41 extend in the X-axis direction. Optical waveguide 20 extends from one end of the substrate 10 in the X-axis direction beyond the center of the substrate 10 to a position that does not reach the other end of the substrate 10. One end portion of optical waveguide 20 is positioned at an end portion of substrate 10 and serves as incident port IN. The other end portion of optical waveguide 20 has a tapered portion 70. Portions of optical waveguide 20 other than tapered portion 70 are linear. A portion of optical waveguide 20 close to incident port IN is exposed from bonding layer 42 of semiconductor element 40. Tapered portion 70 and a portion close to tapered portion 70 of optical waveguide 20 are covered with bonding layer 42.

Optical waveguide 41 extends from approximately the center of the substrate 10 in the X-axis direction to another end portion of substrate 10 opposite to incident port IN. The end portion of optical waveguide 41 is exit port OUT.

Optical waveguide 20 has tapered portion 70 at a distal end portion opposite to incident port IN. Tapered portion 70 of optical waveguide 20 and optical waveguide 41 form directional coupler 21. Tapered portion 70 has a symmetrical shape with respect to the X-axis. One end portion 20a (first end portion) and another end portion 20b (second end portion) in the Y-axis direction of optical waveguide 20 are inclined from the X-axis and approach optical waveguide 41. End portion 20a and end portion 20b form tapered portion 70. Tapered portion 70 is thicker as it goes away from the tip of optical waveguide 20 and thinner as it approaches toward the tip.

Coupling length L1 of directional coupler 21 between optical waveguide 20 and optical waveguide 41 illustrated in FIG. 13A is, for example, 200 μm. In optical waveguide 20, a distance L2 from an end of bonding layer 42 to tapered portion 70 is, for example, 15 μm. In the two end portions of tapered portion 70, a width W4 at the end portion closer to incident port IN is, for example, 1200 nm. A width W5 of optical waveguide 20 at the other end portion (tip) of tapered portion 70 is less than width W4, and is 400 nm, for example. A thickness T1 of optical waveguide 20 illustrated in FIG. 13B is, for example, 220 nm. A distance g between the center (line C1) of optical waveguide 20 and the center (line C2) of optical waveguide 41 is equal to or greater than 0 nm, and may be several hundred nm. When distance g is 0 nm, the center of optical waveguide 20 and the center of optical waveguide 41 overlap each other.

Light is incident on optical waveguide 20 from incident port IN. The light propagates through optical waveguide 20 and transmits from optical waveguide 20 to optical waveguide 41 at directional coupler 21. The light transmitted to optical waveguide 41 is emitted from exit port OUT of optical waveguide 41.

According to the fourth embodiment, tapered portion 70 of optical waveguide 20 and optical waveguide 41 form directional coupler 21. Therefore, high coupling efficiency can be obtained. Light passes from optical waveguide 20 to optical waveguide 41 at directional coupler 21. Optical loss can be suppressed, and light can be emitted from exit port OUT.

Si layer 16 may be etched to provide tapered portion 70 in optical waveguide 20. It is not necessary to form a multi-stage taper in semiconductor element 40. The process is simplified. Deviations may occur in dimensions such as widths W4 and W5 of optical waveguide 20, width W2 of optical waveguide 41, and distance g between the optical waveguides. According to the fourth embodiment, since optical waveguide 20 has tapered portion 70, tolerance with respect to dimensional deviation is improved. Even when a dimensional error occurs, high coupling efficiency is maintained, and deterioration of characteristics is suppressed.

### Fifth Embodiment

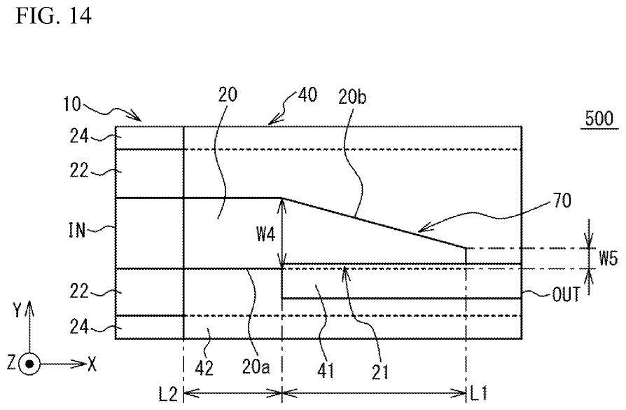

FIG. 14 is a plan view illustrating a semiconductor optical device 500 according to a fifth embodiment. A description of the same configuration as any one of the first embodiment to the fourth embodiment will be omitted. Tapered portion 70 of optical waveguide 20 and optical waveguide 41 form directional coupler 21. Tapered portion 70 has an asymmetric shape with respect to the X-axis. One end portion 20a (first end portion) of optical waveguide 20 in the Y-axis direction is parallel to the X-axis and linearly extends. Another end portion 20b (second end portion) of optical waveguide 20 is inclined from the X-axis and approaches optical waveguide 41. End portion 20a and end portion 20b form tapered portion 70.

According to the fifth embodiment, tapered portion 70 of optical waveguide 20 and optical waveguide 41 form directional coupler 21. Therefore, high coupling efficiency can be obtained. Light passes from optical waveguide 20 to optical waveguide 41 at directional coupler 21. Optical loss can be suppressed, and light can be emitted from exit port OUT. According to the fifth embodiment, since optical waveguide 20 has tapered portion 70, tolerance with respect to dimensional deviation is improved.

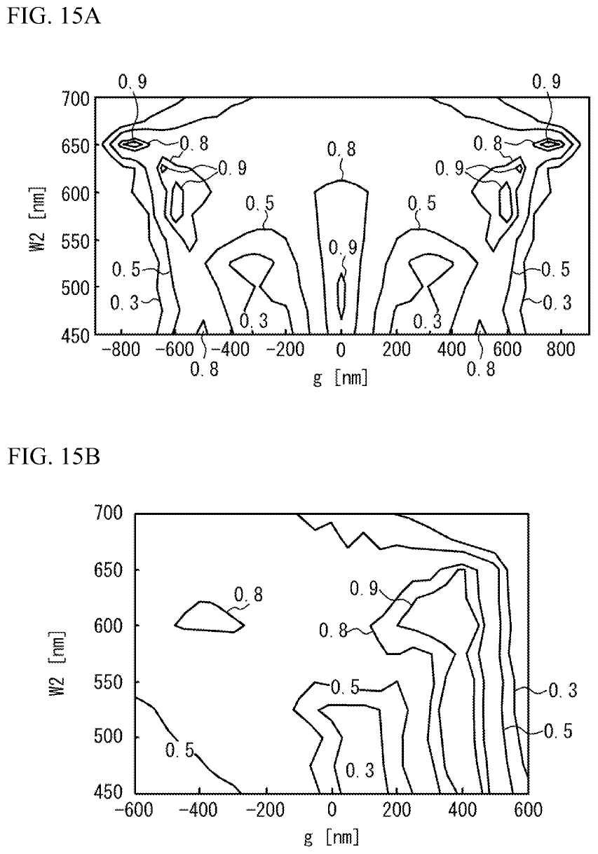

FIGS. 15A and 15B are diagrams illustrating calculation results of coupling efficiency. It is assumed that the TEO mode enters from optical waveguide 20 and is excited in optical waveguide 41. The worst values of coupling efficiency at three wavelengths (1530 nm, 1547.5 nm, 1565 nm) are calculated by the full vector beam propagation method. The coupling efficiencies in FIGS. 15A and 15B are normalized by the maximum value of the coupling efficiency in the fifth embodiment (one sided taper example). The numbers (0.3, 0.8, 0.9, etc.) in FIGS. 15A and 15B represent normalized coupling efficiencies. The maximum value of the normalized coupling efficiency is 1. As the coupling efficiency decreases from 1, the characteristics deteriorate.

Each horizontal axis of FIGS. 15A and 15B represents distance g between the centers of the optical waveguides. The vertical axis represents width W2 of optical waveguide 41. The coupling efficiency for changes in distance g and width W2 is evaluated.

FIG. 15A illustrates the coupling efficiency in the fourth embodiment. As illustrated in FIG. 15A, distance g varies from approximately −800 nm to 800 nm. When distance g is 0, the center of optical waveguide 20 overlaps with the center of optical waveguide 41. When distance g is positive, the center of optical waveguide 20 is located to the left of the center of optical waveguide 41 in FIG. 13B. When distance g is negative, the center of optical waveguide 20 is located to the right of the center of optical waveguide 41 in FIG. 13B. Width W2 is varied from 450 nm to 700 nm.

In the example of FIG. 13A, since tapered portion 70 has a symmetrical shape, the coupling efficiency of FIG. 15A is symmetrical with respect to distance g=0. When distance g is around 0 and width W2 is from 450 nm to 600 nm, the normalized coupling efficiency is 0.8 or more. When distance g is from 500 nm to 600 nm and width W2 is from 550 nm to around 600 nm, the coupling efficiency is 0.8 or more. When distance g is from 100 nm to 400 nm and width W2 is from 450 nm to about 550 nm, the coupling efficiency is 0.5 or less. In the case where the coupling efficiency is 0.5 or less, it is probable that unwanted mode conversion occurs.

FIG. 15B illustrates the coupling efficiency in the fifth embodiment. As illustrated in FIG. 15B, distance g is varied from −600 nm to 600 nm. Width W2 is varied from 450 nm to 700 nm.

When distance g is from about 0 to 200 nm and width W2 is from 450 nm to 550 nm, the coupling efficiency is 0.5 or less. When distance g is 200 nm or more, high coupling efficiency can be obtained in a wide range. When distance g is about 400 nm and width W2 is from 450 nm to 650 nm, the coupling efficiency is 0.9 or more.

As illustrated in FIGS. 15A and 15B, the coupling efficiency can be improved by setting distance g and width W2 within appropriate ranges. In the example of FIG. 15A, the coupling efficiency can be set to 0.8 or more by setting width W2 within the 150 nm range from 450 nm to 600 nm even if distance g has errors of about 100 nm with 0 as the center. In the example of FIG. 15B, the coupling efficiency can be 0.8 or more even if distance g has errors of about ±150 nm with 400 nm as the center, and width W2 has errors of about ±100 nm with 550 nm as the center. High coupling efficiency can be obtained over the entire C-band.

Although the embodiments of the present disclosure have been described in detail, the present disclosure is not limited to the specific embodiments, and various modifications and changes can be made within the scope of the present disclosure described in the claims.

What is claimed is:

1. A semiconductor optical device comprising:
a substrate formed of silicon and having a first optical waveguide; and
a semiconductor element formed of a compound semiconductor and having a second optical waveguide, the semiconductor element being bonded to an upper surface of the substrate,
wherein the first optical waveguide and the second optical waveguide form a directional coupler.

2. The semiconductor optical device according to claim 1,
wherein the first optical waveguide has a bent shape to approach the second optical waveguide.

3. The semiconductor optical device according to claim 1,
wherein the first optical waveguide has a first part and a second part,
wherein a distance between the second part and the second optical waveguide is smaller than a distance between the first part and the second optical waveguide, and
wherein the second part and the second optical waveguide form the directional coupler.

4. The semiconductor optical device according to claim 1,
wherein the second optical waveguide is positioned above one end portion of the first optical waveguide in a width direction and does not extend to another end portion of the first optical waveguide.

5. The semiconductor optical device according to claim 1,
wherein, in a width direction of each of the first optical waveguide and the second optical waveguide, a center of the second part of the first optical waveguide is spaced from a center of the second optical waveguide.

6. The semiconductor optical device according to claim 5,
wherein, in a direction in which the substrate and the semiconductor element are bonded together, at least a portion of the second part of the first optical waveguide does not overlap the second optical waveguide.

7. The semiconductor optical device according to claim 3, comprising:
a phase adjustment portion provided at the first part of the first optical waveguide.

8. The semiconductor optical device according to claim 1,
wherein the directional coupler formed by the first optical waveguide and the second optical waveguide is a plurality of directional couplers, and
wherein the plurality of directional couplers are arranged in an extension direction of each of the first optical waveguide and the second optical waveguide.

9. The semiconductor optical device according to claim 1,
wherein the semiconductor element has a first semiconductor layer and a mesa,
wherein the first semiconductor layer is bonded to the upper surface of the substrate, and
wherein the mesa projects from the first semiconductor layer toward a direction opposite to the substrate and has the second optical waveguide.

10. The semiconductor optical device according to claim 9,
wherein the mesa has a second semiconductor layer, a third semiconductor layer, and a fourth semiconductor layer,
wherein the second semiconductor layer, the third semiconductor layer, and the fourth semiconductor layer are stacked in this order on the first semiconductor layer, and
wherein the third semiconductor layer has a multiple quantum well structure.

11. The semiconductor optical device according to claim 1,
wherein the substrate has a first layer, a second layer, and a third layer stacked in order,
wherein the first layer and the third layer are formed of silicon,
wherein the second layer is formed of silicon oxide, and
wherein the semiconductor element is bonded to the third layer.

12. The semiconductor optical device according to claim 1,
wherein the first optical waveguide of the substrate includes two first optical waveguides, and
wherein the two first optical waveguides and the second optical waveguide form the directional coupler.

13. The semiconductor optical device according to claim 1,
wherein the semiconductor element has an optical gain, and
wherein the semiconductor element functions as a laser element.

14. The semiconductor optical device according to claim 1,
wherein the first optical waveguide has a tapered portion,
wherein the tapered portion becomes thinner toward a tip of the first optical waveguide, and
wherein the tapered portion of the first optical waveguide and the second optical waveguide form the directional coupler.

15. The semiconductor optical device according to claim 14,
wherein the tapered portion of the first optical waveguide has an asymmetrical shape with respect to a direction in which the first optical waveguide extends.

16. The semiconductor optical device according to claim 15,
wherein a first end portion of the first optical waveguide is parallel to the direction in which the first optical waveguide extends, a second end portion of the first optical waveguide approaches the second optical waveguide, and the tapered portion forms the asymmetrical shape.

17. The semiconductor optical device according to claim 14,
wherein the tapered portion of the first optical waveguide has a symmetrical shape with respect to a direction in which the first optical waveguide extends.

18. A method of manufacturing a semiconductor optical device, the method comprising:
bonding a semiconductor element formed of a compound semiconductor to an upper surface of a substrate formed of silicon and having a first optical waveguide; and
forming a second optical waveguide at the semiconductor element,
wherein the first optical waveguide and the second optical waveguide form a directional coupler.
